(19) United States
(12) Patent Application Publication
(10) Pub. No.: US 2024/0154381 A1
(43) Pub. Date: May 9, 2024

(54) GAS LASER APPARATUS, GAS LASER APPARATUS MAINTENANCE METHOD, AND ELECTRONIC DEVICE MANUFACTURING METHOD

(71) Applicant: Gigaphoton Inc., Tochigi (JP)

(72) Inventors: Junichi FUJIMOTO, Oyama-shi (JP); Akira SUWA, Oyama-shi (JP)

(73) Assignee: Gigaphoton Inc., Tochigi (JP)

(21) Appl. No.: 18/408,770

(22) Filed: Jan. 10, 2024

Related U.S. Application Data
(63) Continuation of application No. PCT/JP2021/029388, filed on Aug. 6, 2021.

(51) Int. Cl. H01S 3/097; H01S 3/038; H01S 3/041; H01S 3/22

(52) U.S. Cl. CPC H01S 3/09702; H01S 3/038; H01S 3/041; H01S 3/2207

(57) ABSTRACT

A gas laser apparatus includes a voltage application circuit, a chamber device that includes an electrode and is configured to output light generated when a voltage is applied to the electrode from the voltage application circuit, a first pallet that includes a mounting surface on which the chamber device and the voltage application circuit are disposed in parallel with each other, and a housing unit in and out of which the first pallet is movable by movement in an in-plane direction of the mounting surface.

### CROSS-REFERENCE TO RELATED APPLICATIONS

The present application is a continuation application of International Application No. PCT/JP2021/029388, filed on Aug. 6, 2021, the entire contents of which are hereby incorporated by reference.

### BACKGROUND

### 1. Technical Field

The present disclosure relates to a gas laser apparatus, a gas laser apparatus maintenance method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248.0 nm and an ArF excimer laser apparatus that outputs a laser beam having a wavelength of about 193.4 nm are used.

Spectral linewidths of spontaneous oscillation beams of the KrF excimer laser apparatus and the ArF excimer laser apparatus are as wide as from 350 μm to 400 pm. Therefore, when a projection lens is formed of a material that transmits ultraviolet light such as a KrF laser beam and an ArF laser beam, chromatic aberration may occur. As a result, the resolution may decrease. Given this, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (etalon or grating, etc.) may be provided in order to narrow the spectral linewidth. Hereinafter, a gas laser apparatus with a narrowed spectral linewidth is referred to as a line narrowing gas laser apparatus.

### LIST OF DOCUMENT

### Patent Document

Patent Document 1: Japanese Unexamined Patent Application Publication No. 8-56035

### SUMMARY

A gas laser apparatus according to one aspect of the present disclosure may include a voltage application circuit, a chamber device, a first pallet, and a housing unit. The chamber device may include an electrode and may be configured to output light generated when a voltage is applied to the electrode from the voltage application circuit. The first pallet may include a mounting surface on which the chamber device and the voltage application circuit are disposed in parallel with each other. The first pallet may be movable in and out of the housing unit by movement in an in-plane direction of the mounting surface.

A gas laser apparatus maintenance method according to one aspect of the present disclosure may include, when replacing a chamber device and a voltage application circuit of a gas laser apparatus including the voltage application circuit, the chamber device that includes an electrode and is configured to output light generated when a voltage is applied to the electrode from the voltage application circuit, a first pallet that includes a mounting surface on which the chamber device and the voltage application circuit are disposed in parallel with each other, and a housing unit in and out of which the first pallet is movable by movement in an in-plane direction of the mounting surface, replacing the first pallet altogether.

An electronic device manufacturing method according to one aspect of the present disclosure may include generating a laser beam by a gas laser apparatus, outputting the laser beam to an exposure apparatus, and exposing a photosensitive substrate to the laser beam within the exposure apparatus to manufacture an electronic device. The gas laser apparatus may include a voltage application circuit, a chamber device that includes an electrode and is configured to output light generated when a voltage is applied to the electrode from the voltage application circuit, a first pallet that includes a mounting surface on which the chamber device and the voltage application circuit are disposed in parallel with each other, and a housing unit in and out of which the first pallet is movable by movement in an in-plane direction of the mounting surface.

### BRIEF DESCRIPTION OF THE DRAWINGS

An embodiment of the present disclosure will be described below, by way of example only, with reference to the accompanying drawings.

FIG. 1 is a schematic diagram illustrating an overall configuration example of an electronic device manufacturing apparatus.

FIG. 2 is a schematic diagram illustrating an overall configuration example of a gas laser apparatus of a comparative example.

FIG. 3 is a front view of a housing unit in the comparative example.

FIG. 4 is a diagram illustrating a part of a flowchart of a maintenance method of the gas laser apparatus in the comparative example.

FIG. 5 is a diagram illustrating a remaining part of the flowchart of the maintenance method of the gas laser apparatus in the comparative example.

FIG. 6 is a side view of the housing unit in the embodiment when viewed from an exit window.

FIG. 7 is a top view of the housing unit illustrated in FIG. 6.

FIG. 8 is a top view illustrating a positional relationship of a pedestal.

FIG. 9 is a diagram illustrating an example of a flowchart of a maintenance method of a gas laser apparatus in the embodiment.

FIG. 10 is a diagram illustrating another example of the flowchart of the maintenance method of the gas laser apparatus in the embodiment.

FIG. 11 is a side view of the housing unit in a modification of the embodiment.

### DESCRIPTION OF EMBODIMENT

1. Description of electronic device manufacturing apparatus used in exposure process of electronic device
2. Description of gas laser apparatus of comparative example
   2.1 Configuration
   2.2 Operation
   2.3 Maintenance method of gas laser apparatus
   2.4 Problem
3. Description of gas laser apparatus of embodiment
   3.1 Configuration
   3.2 Maintenance method of gas laser apparatus
   3.3 Operation and Effect

Hereinafter, an embodiment of the present disclosure will be described in detail with reference to the drawings.

The embodiment described below shows some examples of the present disclosure and do not limit the contents of the present disclosure. In addition, all configurations and operations described in the embodiments are not necessarily essential as configurations and operations of the present disclosure. Here, the same components are denoted by the same reference numerals, and redundant description thereof is omitted.

### 1. Description of Electronic Device Manufacturing Apparatus Used in Exposure Process of Electronic Device

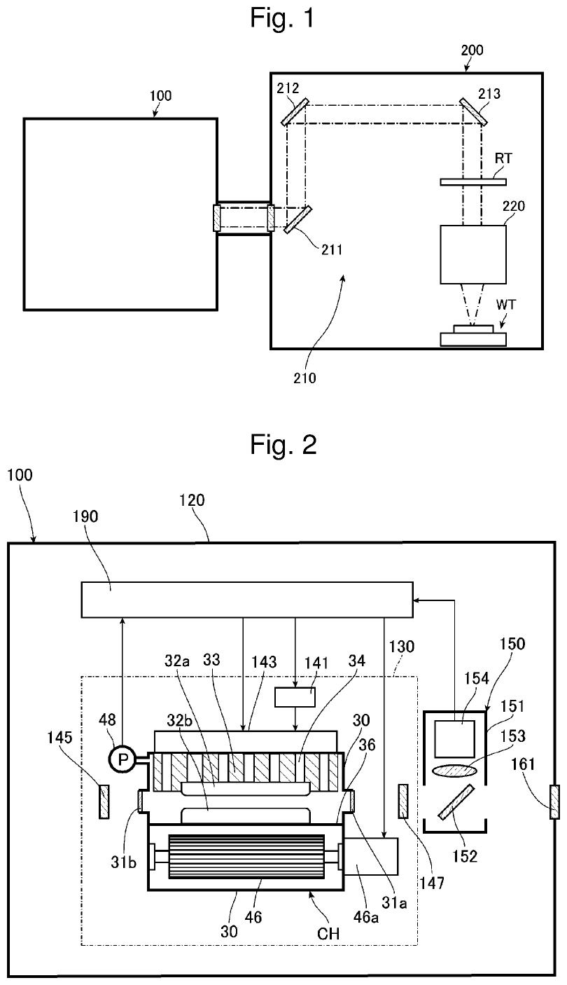

FIG. 1 is a schematic diagram illustrating an overall configuration example of an electronic device manufacturing apparatus used in an exposure process of an electronic device. As illustrated in FIG. 1, the manufacturing apparatus used in the exposure process includes a gas laser apparatus 100 and an exposure apparatus 200. The exposure apparatus 200 includes an illumination optical system 210 including a plurality of mirrors 211, 212 and 213, and a projection optical system 220. The illumination optical system 210 illuminates a reticle pattern of a reticle stage RT by a laser beam entering from the gas laser apparatus 100. The projection optical system 220 performs reduction projection of the laser beam transmitted through a reticle and forms an image on an unillustrated workpiece disposed on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser beam reflecting the reticle pattern. By transferring a device pattern onto the semiconductor wafer through the exposure process as described above, a semiconductor device, which is the electronic device, can be manufactured.

### 2. Description of Gas Laser Apparatus of Comparative Example

2.1 Configuration

The gas laser apparatus 100 of a comparative example will be described. The comparative example of the present disclosure is an example recognized by the applicant as known only by the applicant, and is not a publicly known example admitted by the applicant.

FIG. 2 is a schematic diagram illustrating an overall configuration example of the gas laser apparatus 100 of the present example.

The gas laser apparatus 100 is, for example, an ArF excimer laser apparatus using a mixed gas including argon (Ar), fluorine (F₂) and neon (Ne). The gas laser apparatus 100 outputs a laser beam having a center wavelength of about 193.4 nm. The gas laser apparatus 100 may be a gas laser apparatus other than the ArF excimer laser apparatus, and may be, for example, a KrF excimer laser apparatus using a mixed gas including krypton (Kr), F₂, and Ne. In this case, the gas laser apparatus 100 outputs the laser beam having the center wavelength of about 248.0 nm. The mixed gas containing Ar, F₂ and Ne, which are laser media, or the mixed gas containing Kr, F₂ and Ne, which are the laser media, may be referred to as a laser gas. In the mixed gas used in each of the ArF excimer laser apparatus and the KrF excimer laser apparatus, helium (He) may be used instead of Ne.

The gas laser apparatus 100 of the present example mainly includes a housing unit 120, and a laser oscillator 130, a monitor module 150, an unillustrated laser gas supply device, an unillustrated laser gas exhaust device, an unillustrated temperature regulator, and a laser processor 190 that are disposed in an internal space of the housing unit 120.

The laser oscillator 130 mainly includes a chamber device CH, a charger 141, a pulse power module 143, a rear mirror 145, and an output coupling mirror 147.

FIG. 2 illustrates an internal configuration of the chamber device CH when viewed from a direction substantially perpendicular to a traveling direction of the laser beam.

The chamber device CH mainly includes a housing 30, a pair of windows 31a and 31b, a pair of electrodes 32a and 32b, an insulating part 33, a feedthrough 34, an electrode holder part 36, a cross flow fan 46, and a pressure sensor 48.

The housing 30 encloses the laser gas. The housing 30 includes an internal space in which light is generated by excitation of the laser medium in the laser gas. The laser gas is supplied from the laser gas supply device to the internal space of the housing 30 via an unillustrated gas pipe. The light generated by the excitation of the laser medium travels to the windows 31a and 31b.

The window 31a is disposed on a front-side wall surface of the housing 30 in the traveling direction of the laser beam from the gas laser apparatus 100 to the exposure apparatus 200, and the window 31b is disposed on a rear-side wall surface of the housing 30 in the traveling direction.

The electrodes 32a and 32b are disposed to face each other in the internal space of the housing 30, and a longitudinal direction of the electrodes 32a and 32b is along the traveling direction of the light generated by a high voltage applied between the electrode 32a and the electrode 32b. A space between the electrode 32a and the electrode 32b in the housing 30 is sandwiched between the window 31a and the window 31b. The electrodes 32a and 32b are discharge electrodes for exciting the laser medium by glow discharge. In the present example, the electrode 32a is a cathode and the electrode 32b is an anode.

The electrode 32a is supported by the insulating part 33. The insulating part 33 closes an opening formed on the housing 30. The insulating part 33 includes an insulator. In addition, the feedthrough 34 made of a conductive member is disposed at the insulating part 33. The feedthrough 34 applies the voltage supplied from the pulse power module 143 to the electrode 32a.

The electrode 32b is supported by the electrode holder part 36 and is electrically connected to the electrode holder part 36.

The cross flow fan 46 is disposed in the internal space of the housing 30 on a side opposite to the electrode 32b with respect to the electrode holder part 36. In the internal space of the housing 30, a space in which the cross flow fan 46 is disposed is in communication with the space on the side of the electrodes 32a and 32b. In the space in which the cross flow fan 46 is disposed, an unillustrated heat exchanger is disposed beside the cross flow fan 46. The cross flow fan 46 is connected to a motor 46a disposed outside the housing 30, and is rotated by the rotation of the motor 46a. The cross flow fan 46 makes the laser gas flow between the electrodes 32a and 32b by the rotation. The laser gas is circulated by the cross flow fan 46 in the order of the cross flow fan 46, the space between the electrode 32a and the electrode 32b, the heat exchanger, and the cross flow fan 46. The majority of the laser gas that is made to flow by the cross flow fan 46 passes through the heat exchanger and heat of the laser gas is removed by the heat exchanger. The motor 46a is electrically connected to the laser processor 190, and ON, OFF and a rotational speed of the motor 46a are adjusted under control of the laser processor 190. Accordingly, the laser processor 190 controls the motor 46a to adjust a circulation speed of the laser gas which is circulated in the internal space of the housing 30.

The charger 141 is a DC power supply device that charges an unillustrated capacitor provided in the pulse power module 143 with a predetermined voltage. The charger 141 is disposed outside the housing 30 and is connected to the pulse power module 143. The pulse power module 143 includes an unillustrated switch that is controlled by the laser processor 190. The pulse power module 143 is a voltage application circuit that, when the switch is turned from OFF to ON under the control, boosts the voltage applied from the charger 141 to generate a pulsed high voltage, and applies the high voltage to the electrodes 32a and 32b. When the high voltage is applied, discharge occurs between the electrode 32a and the electrode 32b. The laser medium in the housing 30 is excited by the energy of the discharge. When the excited laser medium shifts to a ground level, the light is output and the output light travels to the windows 31a and 31b and passes through the windows 31a and 31b. In this manner, the chamber device CH includes the electrodes 32a and 32b inside the housing 30, and outputs the light generated by applying the voltage to the electrodes 32a and 32b from the pulse power module 143.

The rear mirror 145 faces the window 31b, reflects the laser beam output from the window 31b at a high reflectance and returns the laser beam to the housing 30. The output coupling mirror 147 faces the window 31a, transmits a part of the laser beam output from the window 31a, reflects the other part, and returns the other part to the internal space of the housing 30 via the window 31a. Thus, the rear mirror 145 and the output coupling mirror 147 configure a Fabry-Perot laser resonator, and the housing 30 is disposed on an optical path of the laser resonator. The rear mirror 145 and the output coupling mirror 147 are fixed in the housing unit 120 by an unillustrated optical path pipe.

Instead of the rear mirror 145, an unillustrated line narrowing module which line-narrows the laser beam may be disposed. The line narrowing module includes a prism, a grating, and a rotation stage. The prism, the grating, and the rotation stage are disposed in an internal space of an unillustrated housing.

The prism expands a beam width of the light output from the window 31b and causes the light to enter the grating. The prism also reduces the beam width of the light reflected from the grating and returns the light to the internal space of the housing 30 via the window 31b. At least one prism may be disposed.

A surface of the grating is made of a material having a high reflectance, and a large number of grooves are provided on the surface at predetermined intervals. The grating is a dispersive optical element. A cross-sectional shape of each groove is, for example, a right-angled triangle. The light entering the grating from the prism is reflected by these grooves and diffracted in a direction corresponding to the wavelength of the light. The grating is disposed in Littrow arrangement so that an incident angle of the light entering the grating from the prism coincides with a diffracting angle of the diffracted light having a desired wavelength. As a result, light having a wavelength in the vicinity of the desired wavelength is returned to the housing 30 via the prism.

The rotation stage supports the prism and rotates the prism. By rotating the prism, the incident angle of the light on the grating is changed. Thus, by rotating the prism, the wavelength of light returning from the grating to the housing 30 via the prism can be selected.

The output coupling mirror 147 and the grating provided across the housing 30 configure the laser resonator.

The monitor module 150 is disposed on the optical path of the laser beam transmitted through the output coupling mirror 147. The monitor module 150 mainly includes a housing 151, and a beam splitter 152, a light condensing lens 153 and a photosensor 154 that are disposed in an internal space of the housing 151. The housing 151 is fixed in the housing unit 120 by an unillustrated holder. An opening is formed in the housing 151, and the light from the output coupling mirror 147 passes through the opening and travels to the beam splitter 152.

The beam splitter 152 transmits the laser beam transmitted through the output coupling mirror 147 to an exit window 161 to be described later with a high transmittance, and reflects a part of the laser beam toward the light condensing lens 153. The light condensing lens 153 condenses the laser beam on a light receiving surface of the photosensor 154. The photosensor 154 measures energy E of the laser beam entering the light receiving surface. The photosensor 154 is electrically connected to the laser processor 190 and outputs a signal indicating the measured energy E to the laser processor 190.

An opening is formed on a side opposite to the output coupling mirror 147 in the housing 151 of the monitor module 150. In the housing unit 120, the exit window 161 is provided on the side opposite to the beam splitter 152 with respect to the opening. The exit window 161 is fixed to the housing unit 120. The light transmitted through the beam splitter 152 of the monitor module 150 is output from the exit window 161 to the exposure apparatus 200 outside the housing unit 120.

The pressure sensor 48 measures a pressure in the internal space of the housing 30. The pressure sensor 48 is electrically connected to the laser processor 190 and outputs a signal indicating the measured pressure to the laser processor 190.

The laser gas supply device is provided with a valve and a flow rate control valve that are unillustrated, and is connected with an unillustrated gas pipe connected to the housing 30. The laser gas supply device supplies the laser gas to the internal space of the housing 30 from an unillustrated laser gas supply source disposed outside the housing unit 120 via a gas pipe in response to a control signal from the laser processor 190. An unillustrated gas pipe connected to the housing 30 is connected to the laser gas exhaust device. The laser gas exhaust device includes an unillustrated exhaust pump, and exhausts the gas in the internal space of the housing 30 via the gas pipe by the exhaust pump. The temperature regulator is a chiller that supplies a cooling medium to the housing 30 via an unillustrated water pipe connected to the housing 30 from an unillustrated pump of the temperature regulator, and cools the housing 30 by the cooling medium. The temperature regulator is electrically connected to the laser processor 190. When an unillustrated temperature sensor outputs a signal indicating a temperature of the internal space of the housing 30 to the laser processor 190, the laser processor 190 outputs a signal indicating the temperature of the cooling medium to the temperature regulator based on the signal. The temperature regulator adjusts the temperature of the cooling medium based on the signal from the laser processor 190. The cooling medium is a liquid, but may also be a gas.

The laser processor 190 of the present disclosure is a processing device including a storage device in which a control program is stored and a CPU (central processing unit) which executes the control program. The laser processor 190 is specifically configured or programmed to execute various processes included in the present disclosure. The laser processor 190 controls the entire gas laser apparatus 100. The laser processor 190 is electrically connected to an unillustrated exposure processor of the exposure apparatus 200, and transmits and receives various signals to and from the exposure processor.

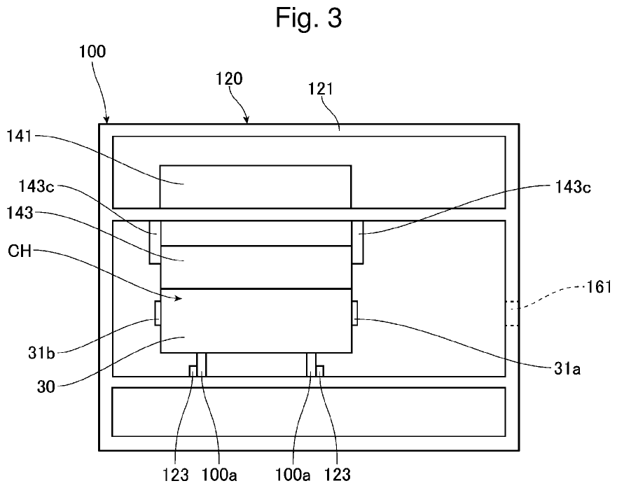

FIG. 3 is a front view of the housing unit 120 in the comparative example. FIG. 3 illustrates a simplified view of the charger 141, the pulse power module 143, and the chamber device CH. Further, in FIG. 3, for the sake of clarity, illustration of the chamber device CH other than the windows 31a and 31b is omitted, and illustration of the rear mirror 145, the output coupling mirror 147, the monitor module 150, and the laser processor 190 is also omitted.

The housing unit 120 includes a plurality of laser frames 121, and examples of a material of the laser frame 121 include a metal such as stainless steel or aluminum. The housing unit 120 configures a box-shaped frame body by the connection of the laser frames 121, and an opening is provided on each of a left side surface, a right side surface, a front surface, a rear surface, an upper surface, and a lower surface of the housing unit 120. The opening has a quadrangular shape and the laser frame 121 is a quadrangular prism member, but the shape of each of the opening and the laser frame 121 is not particularly limited. In addition, the housing unit 120 of the present example may be a housing provided with an opening at least on the front surface.

The housing unit 120 of the present example is divided into three layers in an up-down direction of the housing unit 120. The charger 141 is disposed in the first layer from the top, and the chamber device CH and the pulse power module 143 are disposed in the second layer from the top. The rear mirror 145, the output coupling mirror 147 and the monitor module 150 are disposed in the second layer from the top, and the laser processor 190 is disposed in the first layer from the top. Note that the laser processor 190 may be disposed anywhere as long as it is electrically connected to the respective components of the gas laser apparatus 100.

The chamber device CH is moved in and out of the housing unit 120 for replacement. When moving the chamber device CH in and out of the housing unit 120, the chamber device CH is pulled out from the housing unit 120 to be moved out from the housing unit 120, and the chamber device CH is pushed into the housing unit 120 to be installed to the housing unit 120. In the following, a direction in which the chamber device CH is moved in and out may be referred to as an in-and-out direction. The in-and-out direction is a front-rear direction orthogonal to the up-down direction of the housing unit 120 and a left-right direction which is the traveling direction of the laser beam. The front direction of the front-rear direction is a direction from an open front side to a rear surface side of the housing unit 120, and is a pushing direction of the chamber device CH. Further, the rear direction is a direction from the rear surface side to the front surface side of the housing unit 120, and is a pulling direction of the chamber device CH. In the in-and-out direction of the chamber device CH, a pulling side of the chamber device CH, that is, the open front surface side, is set to be the rear side. In addition, in the in-and-out direction of the chamber device CH, a pushing side of the chamber device CH, that is, the rear surface side, is set to be the front side. Incidentally, when moving the chamber device CH in and out of the housing unit 120, the chamber device CH may be pushed out from the housing unit 120 to be moved out from the housing unit 120, and the chamber device CH may be pulled into the housing unit 120 to be installed to the housing unit 120. Note that the charger 141 and the pulse power module 143 are also moved in and out of the housing unit 120 in the same manner as the chamber device CH for the replacement.

The charger 141 is mounted on a plurality of unillustrated laser frames extending in the in-and-out direction. The laser frames are disposed in parallel. Note that a flat plate material may be disposed in the housing unit 120, and the charger 141 may be mounted on the flat plate material. The charger 141 is electrically connected to the pulse power module 143 via an unillustrated wire.

The pulse power module 143 is fixed to the upper surface of the housing 30 of the chamber device CH with a screw or the like. The pulse power module 143 is connected to the laser frame 121 via an elevator 143c disposed at both ends of the upper part of the pulse power module 143. The elevator 143c can raise and lower the pulse power module 143 in the up-down direction. The elevator 143c is configured by, for example, an air spring, and functions as the elevator 143c by injecting or discharging gas such as air or nitrogen from an unillustrated gas supply source to or from the air spring under the control of the laser processor 190. In a state where fixing of the pulse power module 143 and the chamber device CH is released, when the gas is injected into the elevator 143c, the elevator 143c expands, and the pulse power module 143 is raised and disconnected from the chamber device CH by the expansion of the elevator 143c. Accordingly, the pulse power module 143 detached from the chamber device CH and the elevator 143c can be pulled out from the housing unit 120 for the replacement. In addition, a new chamber device CH and a new pulse power module 143 which are replaced are pushed into the housing unit 120 and installed in the housing unit 120. After the new chamber device CH and the new pulse power module 143 are installed, the elevator 143c contracts when the gas is discharged from the elevator 143c, and the pulse power module 143 is lowered and disposed on the chamber device CH by the contraction of the elevator 143c.

The chamber device CH is disposed below the pulse power module 143 in the housing unit 120, and is fixed by an unillustrated fixture. In addition, wheels 100a are disposed on the front, rear, left, and right of a bottom surface of the housing 30 of the chamber device CH. The left and right wheels 100a are disposed between a pair of rails 123 and are capable of traveling along the pair of rails 123 when the chamber device CH is moved in and out. The pair of rails 123 are disposed below the bottom surface of the housing 30, extend along the in-and-out direction, and are parallel to each other. The wheels 100a and the rails 123 are mounted on the unillustrated laser frames extending in the in-and-out direction. The laser frames are disposed in parallel. Note that the flat plate material may be disposed in the housing unit 120, and the wheels 100a and the rails 123 may be mounted on the plate material. The rails 123 guide the chamber device CH in the front-rear direction via the wheels 100a, and position the chamber device CH around the left-right direction and around the front-rear direction.

2.2 Operation

Next, the operation of the gas laser apparatus 100 of the comparative example will be described.

In a state before the gas laser apparatus 100 outputs the laser beam, the laser gas is supplied from the laser gas supply device to the internal space of the housing 30. When the laser gas is supplied, the laser processor 190 controls the motor 46a to rotate the cross flow fan 46. By the rotation of the cross flow fan 46, the laser gas circulates in the internal space of the housing 30.

When the gas laser apparatus 100 outputs the laser beam, the laser processor 190 receives a signal indicating target energy Et and a light emission trigger signal from the exposure processor of the exposure apparatus 200. The target energy Et is a target value of the energy of the laser beam to be used in the exposure process. The laser processor 190 sets a predetermined charging voltage to the charger 141 so that the energy E becomes the target energy Et, and turns ON the switch of the pulse power module 143 in synchronization with the light emission trigger signal. Thus, the pulse power module 143 generates a pulsed high voltage from the electric energy held in the charger 141, and the high voltage is applied between the electrode 32a and the electrode 32b. When the high voltage is applied, the discharge occurs between the electrode 32a and the electrode 32b, and the laser medium contained in the laser gas between the electrode 32a and the electrode 32b is brought into the excited state, and outputs the light when the laser medium returns to a ground state. The output light resonates between the rear mirror 145 and the output coupling mirror 147, and is amplified every time it passes through a discharge space in the internal space of the housing 30, and laser oscillation occurs. A part of the laser beam passes through the output coupling mirror 147 and travels to the beam splitter 152.

A part of the laser beam which has traveled to the beam splitter 152 is reflected by the beam splitter 152 and is received by the photosensor 154. The photosensor 154 measures the energy E of the received laser beam. The photosensor 154 outputs the signal indicating the measured energy E to the laser processor 190. The laser processor 190 feedback controls the charging voltage of the charger 141 so that a difference ΔE between the energy E and the target energy Et is within an allowable range. The laser beam with the difference ΔE within the allowable range passes through the beam splitter 152 and the exit window 161 and enters the exposure apparatus 200. The laser beam is, for example, a pulse laser beam having the center wavelength of 193.4 nm.

The pressure in the internal space of the housing 30 is measured by the pressure sensor 48, and the signal indicating the pressure from the pressure sensor 48 is input to the laser processor 190. When the charging voltage is higher than a maximum value of the allowable range, the laser processor 190 controls the laser gas supply device based on the signal from the pressure sensor 48, and supplies the laser gas to the internal space of the housing 30 until the pressure in the internal space of the housing 30 becomes a predetermined pressure. When the charging voltage is lower than a minimum value of the allowable range, the laser processor 190 controls the laser gas exhaust device based on the signal, and exhausts the laser gas from the internal space of the housing 30 until the pressure becomes the predetermined pressure.

2.3 Maintenance Method of Gas Laser Apparatus

Next, an example of a maintenance method of the gas laser apparatus 100 in the comparative example will be described.

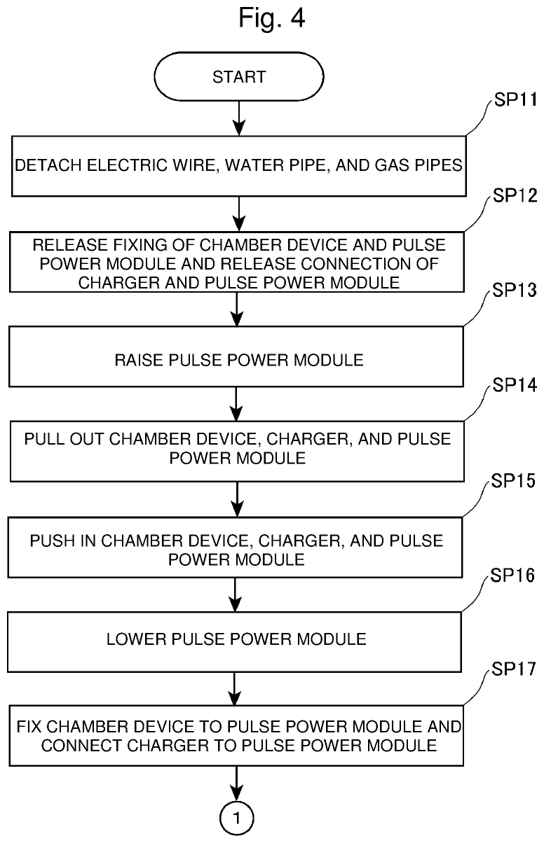

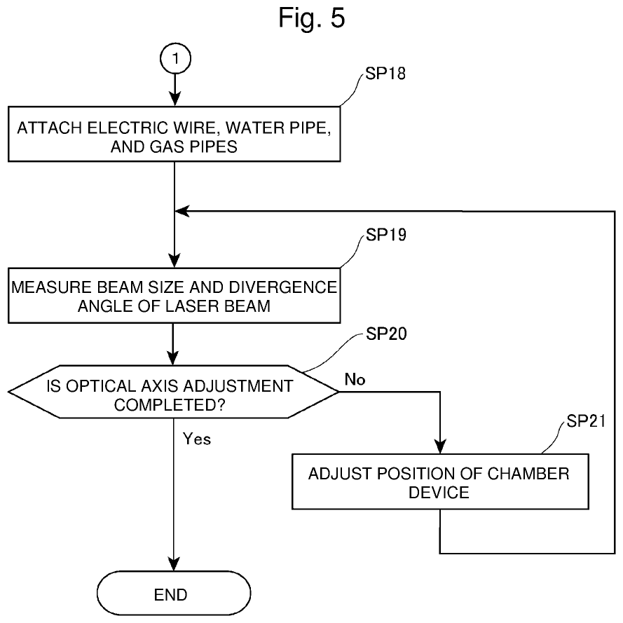

FIG. 4 and FIG. 5 are diagrams illustrating a flowchart of the maintenance method of the gas laser apparatus 100 in the comparative example. The maintenance method is performed when an abnormality occurs in the gas laser apparatus 100, specifically, when a cause of the abnormality is not identified by troubleshooting after the abnormality occurs. In the maintenance method, the chamber device CH, the charger 141, and the pulse power module 143 are replaced. As illustrated in FIG. 4 and FIG. 5, the maintenance method includes step SP11 to step SP21.

(Step SP11)

In the present step, an electric wire, the water pipe of the temperature regulator, the gas pipe of the laser gas supply device, and the gas pipe of the laser gas exhaust device are detached from the housing 30 of the chamber device CH. The electric wire is, for example, a wire that connects the pressure sensor 48 and the laser processor 190. When the electric wire, the water pipe, and the gas pipes are detached, the flow proceeds to step SP12.

(Step SP12)

In the present step, the screw fixing the chamber device CH to the pulse power module 143 is detached, and the fixing of the chamber device CH and the pulse power module 143 is released. In addition, the connection of the charger 141 and the pulse power module 143 is released. Once the fixing and the connection are released, the flow proceeds to step SP13.

(Step SP13)

In the present step, the laser processor 190 causes the gas to be supplied from the unillustrated gas supply source to the elevator 143c which is the air spring. As a result, the elevator 143c expands, and the pulse power module 143 is raised by the expansion and is disconnected from the chamber device CH. When the pulse power module 143 is disconnected from the chamber device CH, the flow proceeds to step SP14.

(Step SP14)

In the present step, the chamber device CH is released from the fixing in the housing unit 120 by the unillustrated fixture and is pulled out from the housing unit 120. At the time, the wheels 100a travel rearward along the rails 123. The chamber device CH, the charger 141, and the pulse power module 143 pulled out from the housing unit 120 are replaced with a new chamber device CH, a new charger 141, and a new pulse power module 143, respectively. Once all of the chamber device CH, the charger 141, and the pulse power module 143 have been replaced, the flow proceeds to step SP15. In the following steps, the new chamber device CH, the new charger 141, and the new pulse power module 143 are simply referred to as the chamber device CH, the charger 141, and the pulse power module 143.

(Step SP15)

In the present step, contrary to step SP14, the charger 141 and the pulse power module 143 are pushed into the housing unit 120. In addition, the chamber device CH is pushed into the housing unit 120 to the lower side of the pulse power module 143. The pushed-in chamber device CH is unmovably fixed by the unillustrated fixture, and the flow proceeds to step SP16.

(Step SP16)

In the present step, contrary to step SP13, the laser processor 190 causes the gas to be exhausted from the elevator 143c by suction of the unillustrated gas supply source. As a result, the elevator 143c contracts, and the pulse power module 143 is lowered by the contraction and is disposed on the chamber device CH. When the pulse power module 143 is placed on the chamber device CH, the flow proceeds to step SP17.

(Step SP17)

In the present step, contrary to step SP12, the chamber device CH is fixed to the pulse power module 143. The charger 141 and the pulse power module 143 are connected to each other. The flow then proceeds to step SP18.

(Step SP18)

In the present step, contrary to the step SP11, the electric wire, the water pipe of the temperature regulator, the gas pipe of the laser gas supply device, and the gas pipe of the laser gas exhaust device are attached to the housing 30 of the chamber device CH. Once the electric wire, the water pipe and the gas pipes are attached, the flow proceeds to step SP19.

(Step SP19)

In the present step, the laser processor 190 drives the gas laser apparatus 100 to output the laser beam from the gas laser apparatus 100. The photosensor 154 measures a beam size and a divergence angle of the laser beam, and outputs a signal indicating a measurement result to the laser processor 190. When the laser processor 190 receives the signal, the flow proceeds to step SP20.

(Step SP20)

In the present step, when the beam size and the divergence angle are the beam size and the divergence angle demanded from the exposure apparatus 200 respectively, optical axis adjustment is completed, and the laser processor 190 stops the gas laser apparatus 100 and ends the flow. Further, in the present step, when the beam size and the divergence angle are not the beam size and the divergence angle demanded from the exposure apparatus 200 respectively, the laser processor 190 stops the gas laser apparatus 100 because the optical axis adjustment is required, and advances the flow to step SP21.

(Step SP21)

In the present step, the fixing of the chamber device CH in the housing unit 120 by the unillustrated fixture is released, and a position of the chamber device CH is adjusted in the front-rear and left-right directions. The position-adjusted chamber device CH is unmovably fixed by the unillustrated fixture, and the flow returns to step SP19.

As described above, in the maintenance method of the present example, all of the chamber device CH, the charger 141, and the pulse power module 143 are replaced with a new chamber device CH, a new charger 141, and a new pulse power module 143. Note that the charger 141 may be pulled out from the housing unit 120 and replaced with a new charger 141 and the new charger 141 may be pushed into the housing unit 120, in step SP13 to step SP16. In addition, the pulse power module 143 may be pulled out from the housing unit 120 and replaced with a new pulse power module 143, and the new pulse power module 143 may be pushed into the housing unit 120, in step SP15.

Note that the chamber device CH may be periodically replaced independently of the charger 141 and the pulse power module 143 due to deterioration of the electrodes 32a and 32b or the like. In this case, in the maintenance method, the chamber device CH may be replaced, and the charger 141 and the pulse power module 143 may not be replaced.

2.4 Problem

In the replacement of the chamber device CH and the pulse power module 143 of the comparative example, the pulse power module 143 needs to be raised and lowered with respect to the chamber device CH, and replacement time becomes long. Therefore, there is a need to shorten the replacement time.

Therefore, in the following embodiment, the gas laser apparatus in which the replacement time can be shortened is exemplified.

### 3. Description of Gas Laser Apparatus of Embodiment

Next, the gas laser apparatus 100 of the embodiment will be described. Any component same as that described above is denoted by an identical sign, and the redundant description is omitted unless specific description is needed. In addition, in some drawings, for the sake of clarity, some members are omitted or simplified.

3.1 Configuration

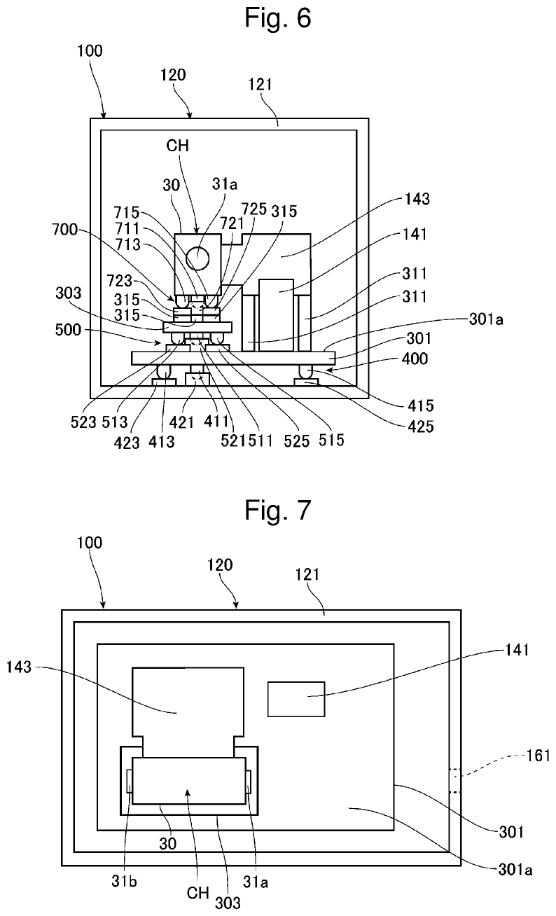

FIG. 6 is a side view of the housing unit 120 in the present embodiment when viewed from the exit window 161. FIG. 7 is a top view of the housing unit 120 illustrated in FIG. 6. FIG. 6 and FIG. 7 illustrate, as in FIG. 3, the simplified view of the charger 141, the pulse power module 143, and the chamber device CH. In addition, in FIG. 6 and FIG. 7, as in FIG. 3, for the sake of clarity, the illustration of the chamber device CH other than the windows 31a and 31b is omitted, and the illustration of the rear mirror 145, the output coupling mirror 147, the monitor module 150, and the laser processor 190 is also omitted.

A configuration of the gas laser apparatus 100 of the present embodiment is different from the configuration of the gas laser apparatus 100 of the comparative example. The gas laser apparatus 100 includes a first pallet 301 including a mounting surface 301a on which the pulse power module 143 and the charger 141 are disposed, and a second pallet 303 on which the chamber device CH is disposed on a mounting surface without the pulse power module 143 being disposed. The charger 141 is disposed directly on the mounting surface 301a of the first pallet 301, the pulse power module 143 is disposed on the mounting surface 301a of the first pallet 301 via a plurality of support members 311, and the chamber device CH is disposed on the mounting surface 301a of the first pallet 301 via the second pallet 303.

The first pallet 301 and the second pallet 303 are flat plates, and examples of a material of the first pallet 301 and the second pallet 303 include a metal such as stainless steel or aluminum. When the first pallet 301 is viewed from above, the mounting surface 301a of the first pallet 301 is larger than the second pallet 303.

The first pallet 301 and the second pallet 303 are housed in the housing unit 120. A configuration of the housing unit 120 of the present embodiment is different from that of the housing unit 120 of the comparative example in the following points. The housing unit 120 is provided with one layer in the up-down direction, and the chamber device CH, the charger 141, the pulse power module 143 which is the voltage application circuit, the first pallet 301, and the second pallet 303 are disposed in the same layer. The chamber device CH, the charger 141, and the pulse power module 143 are parallel to the mounting surface 301a. The rear mirror 145, the output coupling mirror 147, and the monitor module 150, which are not illustrated, are also disposed in the same layer. The rear mirror 145 is disposed on the left side of the window 31b, and the output coupling mirror 147 and the monitor module 150 are disposed between the window 31a and the exit window 161. When the first pallet 301 is viewed from above, the output coupling mirror 147 and the monitor module 150 are disposed on the right side of the first pallet 301. Note that the laser processor 190 may be disposed anywhere as long as it is electrically connected to the respective components of the gas laser apparatus 100.

The first pallet 301 is movable in and out of the housing unit 120 by movement in an in-plane direction of the mounting surface 301a of the first pallet 301. The second pallet 303 is movable in and out of the housing unit 120 by the movement of the first pallet 301 in the in-plane direction, together with the first pallet 301 in a state of being mounted on the first pallet 301. As a result, the chamber device CH, the charger 141, and the pulse power module 143 can be replaced altogether with the first pallet 301. The second pallet 303 is movable in and out of the housing unit 120 in a state where the first pallet 301 remains in the housing unit 120. That is, the second pallet 303 is movable in and out of the housing unit 120 by the movement in the in-plane direction independently of the first pallet 301. As a result, the chamber device CH can be replaced altogether with the second pallet 303 independently of the charger 141 and the pulse power module 143. The chamber device CH and the second pallet 303 are disposed behind the pulse power module 143 in the housing unit 120.

The pulse power module 143 is disposed in parallel with the chamber device CH on the first pallet 301, and the chamber device CH is fixed to the rear surface of the pulse power module 143. A height position of the pulse power module 143 is adjusted by the support members 311, and a connecting part of the pulse power module 143 with the chamber device CH is caused to be at the same height position as the chamber device CH by the adjustment. The support member 311 is a rod-shaped member extending from the bottom surface of the pulse power module 143 toward the first pallet 301. Examples of a material of the support member 311 include a metal such as stainless steel or aluminum. The support member 311 only needs to be able to adjust the height position of the pulse power module 143. The charger 141 is disposed on the right side of the pulse power module 143. A gap is provided between the chamber device CH and the charger 141. The charger 141 is disposed diagonally forward right of the chamber device CH. In addition, the charger 141 is disposed in parallel with the chamber device CH on the first pallet 301 when the chamber device CH is viewed from the front. The pulse power module 143 is electrically connected to the chamber device CH and the charger 141. The electric wire connecting the pulse power module 143 and the charger 141 is not illustrated. The pulse power module 143 and the charger 141 are disposed at positions deviated from the optical path of the light output from the chamber device CH. The charger 141 may be attached to the pulse power module 143. Similarly to the pulse power module 143, the charger 141 is not disposed on the second pallet 303.

The gas laser apparatus 100 of the present embodiment includes positioning units 400, 500 and 700 which are so-called kinematic mounts.

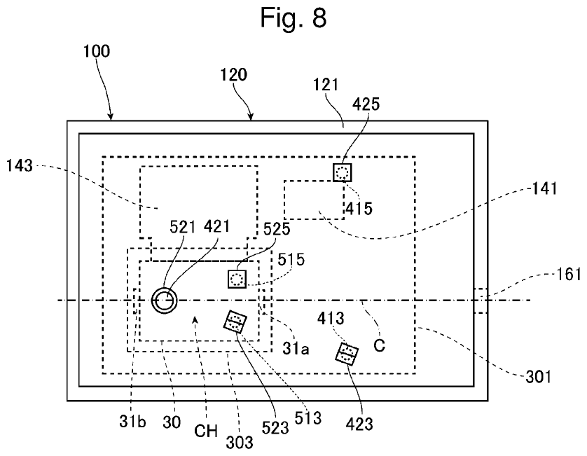

The positioning unit 400 includes legs 411, 413 and 415 disposed on a bottom surface of the first pallet 301 on the opposite side of the mounting surface 301a, and pedestals 421, 423 and 425 disposed in the housing unit 120, and positions the first pallet 301 in the housing unit 120. FIG. 8 is a top view illustrating a positional relationship of the pedestals 421, 423 and 425. In FIG. 8, for the sake of clarity, the first pallet 301, the second pallet 303, the chamber device CH, the charger 141, the pulse power module 143, and the legs 413 and 415 are illustrated by broken lines, and the pedestals 421, 423 and 425 are illustrated by solid lines. Further, in FIG. 8, the leg 411 is not illustrated for the sake of clarity. The leg 411 is a first leg, the leg 413 is a second leg, the leg 415 is a third leg, the pedestal 421 is a first pedestal, the pedestal 423 is a second pedestal, and the pedestal 425 is a third pedestal.

The legs 411, 413 and 415 extend in parallel along a direction perpendicular to the in-plane direction of the mounting surface 301a toward an area of the housing unit 120 facing the bottom surface of the first pallet 301. The perpendicular direction is the up-down direction of the housing unit 120. The legs 411, 413 and 415 are disposed apart from each other in the in-plane direction.

The pedestals 421, 423 and 425 are mounted on an unillustrated laser frame that extends in the in-and-out direction among the laser frames 121. The pedestals 421, 423 and 425 are disposed apart from each other in the in-plane direction of the mounting surface 301a. On the upper surface of each of the pedestals 421, 423 and 425, a hemispherical head of each of the legs 411, 413 and 415 is individually mounted.

A conical depression is provided on the upper surface of the pedestal 421, which is the first pedestal, and the head of the leg 411, which is the first leg, is mounted in the depression. As a result, the leg 411 is hard to move in the in-plane direction of the mounting surface 301a compared to a case where the head is mounted on a flat surface instead of the depression, and thus is restricted from moving. The shape of the depression may be a triangular pyramid shape and is not particularly limited as long as the leg 411 is hard to move in the in-plane direction of the mounting surface 301a.

A groove having a V-shaped cross section is provided on the upper surface of the pedestal 423, which is the second pedestal, and the groove extends toward the bottom of the depression of the pedestal 421 when the pedestal 423 is viewed from above. The head of the leg 413, which is the second leg, is mounted in the groove, and the leg 413 is easy to move in a predetermined direction, which is the direction along the groove in the in-plane direction of the mounting surface 301a, compared to the directions other than the predetermined direction. Further, the leg 413 is easy to move in the predetermined direction compared to the leg 411 mounted in the depression. The shape of the groove is not particularly limited as long as the leg 413 moves as described above.

The upper surface of the pedestal 425, which is the third pedestal, is a flat surface, the head of the leg 415, which is the third leg, is mounted on the upper surface, and the leg 415 is movable along the upper surface of the pedestal 425. That is, the leg 415 is movable in the in-plane direction of the mounting surface 301a. Further, the leg 415 is easy to move in the in-plane direction of the mounting surface 301a compared to the leg 411 mounted in the depression, and is easy to move in the directions other than the predetermined direction compared to the leg 413 mounted in the groove.

When the legs 411, 413 and 415 are mounted on the pedestals 421, 423 and 425 as described above, a gap is provided between the back surface of the first pallet 301 and the housing unit 120 by the legs 411, 413 and 415 and the pedestals 421, 423 and 425.

In the traveling direction of the laser beam from the gas laser apparatus 100 to the exposure apparatus 200, the pedestal 421 is disposed on the rear side of the pedestal 423 and the pedestal 425. When the pedestal 421 is viewed from above, FIG. 8 illustrates an example in which the bottom of the depression of the pedestal 421 overlaps an optical axis C of the light traveling inside the chamber device CH, but at least a part of the pedestal 421 may overlap the optical axis C. When the pedestal 421 is viewed from above, the pedestal 423 and the pedestal 425 do not overlap the optical axis C, and the pedestal 423 is disposed on the side opposite to the pedestal 425 with respect to the optical axis C. The pedestal 423 overlaps the pedestal 421 when viewed from the predetermined direction. Note that at least a part of the pedestal 423 may overlap the pedestal 421.

Examples of a material of the legs 411, 413 and 415 and the pedestals 421, 423 and 425 include a metal such as stainless steel or aluminum.

Next, the positioning unit 500 will be described. The positioning unit 500 includes legs 511, 513 and 515 disposed on the bottom surface of the second pallet 303 on the opposite side of the mounting surface on which the chamber device CH is disposed, and pedestals 521, 523 and 525 disposed on the mounting surface 301a of the first pallet 301, and positions the second pallet 303 on the first pallet 301. In FIG. 8, the pedestal 521 is illustrated larger than the pedestal 421 for the sake of clarity but has the same size, the leg 511 is not illustrated, and the legs 513 and 515 are illustrated by broken lines. The leg 511 is a fourth leg, the leg 513 is a fifth leg, the leg 515 is a sixth leg, the pedestal 521 is a fourth pedestal, the pedestal 523 is a fifth pedestal, and the pedestal 525 is a sixth pedestal.

The legs 511, 513 and 515 extend in parallel along the direction perpendicular to the in-plane direction of the mounting surface 301a toward an area of the mounting surface 301a of the first pallet 301 facing the bottom surface of the second pallet 303. The legs 511, 513 and 515 are disposed apart from each other in the in-plane direction. The pedestals 521, 523 and 525 are disposed apart from each other in the in-plane direction of the mounting surface 301a.

A configuration of the legs 511, 513 and 515 and the pedestals 521, 523 and 525 is the same as the configuration of the legs 411, 413 and 415 and the pedestals 421, 423 and 425. Therefore, the head of the leg 511, which is the fourth leg, is mounted in the depression of the pedestal 521, which is the fourth pedestal, and the leg 511 is hard to move in the in-plane direction of the mounting surface 301a compared to a case where the head is mounted on a flat surface instead of the depression. The leg 513, which is the fifth leg, is mounted on the pedestal 523, which is the fifth pedestal, and is easy to move in a specific direction, which is a direction along the groove of the pedestal 523 in the in-plane direction of the mounting surface 301a, compared to the leg 511. The leg 515, which is the sixth leg, is mounted on the pedestal 525, which is the sixth pedestal, so as to be movable in the in-plane direction of the mounting surface 301a. The leg 515 is easy to move in the in-plane direction of the mounting surface 301a compared to the leg 511, and is easy to move in directions other than the specific direction compared to the leg 513. When the legs 511, 513 and 515 are mounted on the pedestals 521, 523 and 525, a gap is provided between the mounting surface 301a of the first pallet 301 and the bottom surface of the second pallet 303 by the legs 511, 513 and 515 and the pedestals 521, 523 and 525.

The relative position of each of the pedestals 521, 523 and 525 is the same as the relative position of each of the pedestals 421, 423 and 425. Therefore, in the traveling direction of the laser beam from the gas laser apparatus 100 to the exposure apparatus 200, the pedestal 521 is disposed on the rear side of the pedestal 523 and the pedestal 525. When the pedestal 521 is viewed from above, FIG. 8 illustrates an example in which the bottom of the depression of the pedestal 521 overlaps the optical axis C, but at least a part of the pedestal 521 may overlap the optical axis C. When the pedestal 521 is viewed from above, the pedestal 523 and the pedestal 525 do not overlap the optical axis C, and the pedestal 523 is disposed on the side opposite to the pedestal 525 with respect to the optical axis C.

When the pedestal 521 is viewed from above, the pedestal 521 overlaps the pedestal 421. Note that the bottom of the depression of the pedestal 521 may overlap the bottom of the depression of the pedestal 421, and at least a part of the pedestal 521 may overlap the pedestal 421. Alternatively, when the pedestal 521 is viewed from above, at least a part of the pedestal 521 may overlap the pedestal 421 and the optical axis C.

When the pedestal 523 is viewed from above, the groove of the pedestal 523 extends toward the bottom of the depression of the pedestal 521, and the pedestal 523 overlaps the pedestal 521 when viewed from the specific direction. In this case, at least a part of the pedestal 523 may overlap the pedestal 521. When the pedestal 523 is viewed from above, the groove extending in the specific direction of the pedestal 523 may be positioned on an unillustrated line connecting the bottom of the depression of the pedestal 421 and the groove along the predetermined direction of the pedestal 423, and each groove may extend along the same straight line.

Accordingly, the specific direction at the pedestal 523 of the positioning unit 500 may be the same direction as the predetermined direction at the pedestal 423 of the positioning unit 400, and the groove of the pedestal 423 may overlap the groove of the pedestal 523 when viewed from the predetermined direction. In this case, at least a part of the groove of the pedestal 423 may overlap the groove of the pedestal 523 when viewed from the predetermined direction. When the pedestal 525 is viewed from above, the center of the pedestal 525 may be positioned on an unillustrated line connecting the bottom of the depression of the pedestal 421 and the center of the pedestal 425.

Next, the positioning unit 700 will be described. The positioning unit 700 includes legs 711, 713 and 715 disposed on the bottom surface of the housing 30 of the chamber device CH, and pedestals 721, 723 and 725 disposed on the mounting surface of the second pallet 303, and positions the chamber device CH on the second pallet 303. In FIG. 6, the pedestal 721 is disposed behind the pedestals 723 and 725, and a part of the pedestal 721 is hidden by the pedestals 723 and 725.

The legs 711, 713 and 715 extend in parallel along the direction perpendicular to the in-plane direction of the mounting surface 301a toward an area of the mounting surface of the second pallet 303 facing the bottom surface of the housing 30 of the chamber device CH. The legs 711, 713 and 715 are disposed apart from each other in the in-plane direction. The pedestals 721, 723 and 725 are disposed apart from each other in the in-plane direction of the mounting surface 301a. The upper surfaces of the pedestals 721, 723 and 725 face the bottom surface of the housing 30.

A configuration of the legs 711, 713 and 715 and the pedestals 721, 723 and 725 is the same as the configuration of the legs 411, 413 and 415 and the pedestals 421, 423 and 425. Therefore, the head of the leg 711 is mounted in the depression of the pedestal 721, and the leg 711 is hard to move in the in-plane direction of the mounting surface 301a compared to a case where the head is mounted on a flat surface instead of the depression. The leg 713 is mounted on the pedestal 723, and is easy to move in the specific direction, which is the direction along the groove of the pedestal 723 in the in-plane direction of the mounting surface 301a, compared to directions other than the specific direction, and is easy to move in the specific direction compared to the leg 711. The leg 715 is mounted on the pedestal 725 so as to be movable in the in-plane direction of the mounting surface 301a. The leg 715 is easy to move in the in-plane direction of the mounting surface 301a compared to the leg 711, and is easy to move in the directions other than the specific direction compared to the leg 713. The specific direction at the pedestal 723 of the positioning unit 700 is the direction different from the specific direction at the pedestal 523 of the positioning unit 500, but may be the same direction, or may be the same direction as the predetermined direction at the pedestal 423 of the positioning unit 400. When the legs 711, 713 and 715 are mounted on the pedestals 721, 723 and 725, a gap is provided between the bottom surface of the housing 30 of the chamber device CH and the second pallet 303 by the legs and the pedestals.

In the gap between the bottom surface of the housing 30 of the chamber device CH and the second pallet 303, the cooling medium which is the gas supplied from an unillustrated cooling source flows. The cooling medium flows from the window 31b toward the window 31a, but the flowing direction of the cooling medium is not particularly limited. The cooling medium flows directly under the chamber device CH, keeps the temperature of the chamber device CH within a fixed range, and suppresses thermal expansion of the second pallet 303 due to the heat of the chamber device CH. The cooling medium may flow in the gap between the bottom surface of the housing 30 of the chamber device CH and the mounting surface 301a of the first pallet 301. The gap is at least one of the gap between the bottom surface of the housing 30 of the chamber device CH and the second pallet 303 and the gap between the bottom surface of the second pallet 303 and the mounting surface 301a of the first pallet 301.

Since the relative position of each of the pedestals 721, 723 and 725 is the same as the relative position of each of the pedestals 521, 523 and 525, the description will be omitted.

The gas laser apparatus 100 includes heat insulating members 315 disposed between the bottom surface of the housing 30 of the chamber device CH and the second pallet 303. Examples of a material of the heat insulating member 315 include resin such as polyether ether ketone. The three heat insulating members 315 are disposed on the mounting surface of the second pallet 303, and the pedestals 721, 723 and 725 are individually disposed on each of the heat insulating members 315. The heat insulating member 315 insulates the heat from the chamber device CH to the second pallet 303 and the heat from the chamber device CH to the first pallet 301 via the second pallet 303. The heat insulating member 315 may be disposed on the entire mounting surface of the second pallet 303, or in an area of the mounting surface directly under the chamber device CH. Note that the heat insulating member 315 only needs to insulate the heat from the chamber device CH, and therefore may be disposed between the bottom surface of the housing 30 of the chamber device CH and the mounting surface 301a of the first pallet 301 or on the mounting surface 301a.

3.2 Maintenance Method of Gas Laser Apparatus

Next, an example of a maintenance method of the gas laser apparatus 100 in the present embodiment will be described.

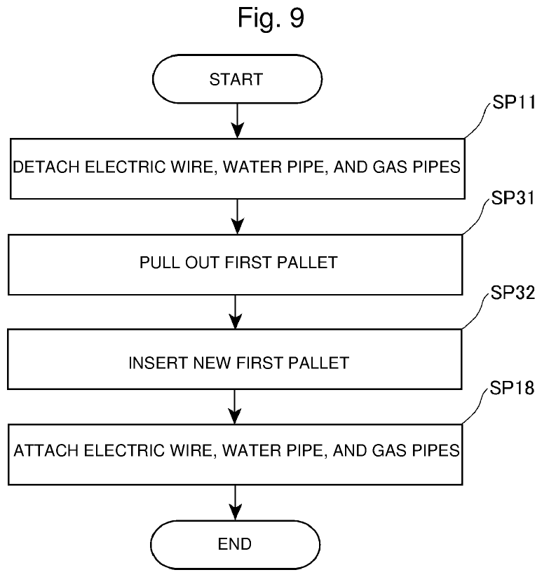

FIG. 9 is a diagram illustrating an example of a flowchart of the maintenance method of the gas laser apparatus 100 in the present embodiment. The maintenance method is performed when an abnormality occurs in the gas laser apparatus 100, specifically, when a cause of the abnormality is not identified by troubleshooting after the abnormality occurs, as in the comparative example. The flowchart of the present embodiment differs from the flowcharts described in FIG. 4 and FIG. 5 in that it includes step SP31 and step SP32 instead of step SP12 to step SP17, and step SP19 to step SP21 are not required. In step SP11, when the electric wire, the water pipe, and the gas pipes are detached, the flow proceeds to step SP31.

(Step SP31)

In the present step, a claw of an unillustrated lift is inserted into the gap between the bottom surface of the first pallet 301 and the housing unit 120, and the first pallet 301 is lifted by the claw of the lift and is pulled out from the housing unit 120 by the lift. As a result, the charger 141, the pulse power module 143, the chamber device CH, and the second pallet 303 are pulled out together with the first pallet 301. The pulled-out first pallet 301 is replaced with a new first pallet 301.

For the new first pallet 301, the charger 141 and the pulse power module 143 are disposed on the first pallet 301. Further, the chamber device CH is positioned on the second pallet 303 by the positioning unit 700, and the second pallet 303 is positioned on the first pallet 301 by the positioning unit 500. In the present step, the first pallet 301 may not be replaced, the charger 141 may be replaced with a new charger 141, the pulse power module 143 may be replaced with a new pulse power module 143, and the second pallet 303 may be replaced with a new second pallet 303 on which a new chamber device CH is mounted. Upon completion of the replacement, the flow proceeds to step SP32.

(Step SP32)

In the present step, the new first pallet 301 is supported on the bottom surface of the new first pallet 301 by the claw of the lift, and is inserted into the housing unit 120 by the lift. On the inserted new first pallet 301, the legs 411, 413 and 415 are individually mounted on the pedestals 421, 423 and 425, and the new first pallet 301 is positioned in the housing unit 120 by the positioning unit 400. Once the positioning is completed, the claw of the lift is pulled out from the housing unit 120, and the flow proceeds to step SP18 and ends.

As described above, in the present flowchart, the chamber device CH, the charger 141, and the pulse power module 143 are replaced altogether.

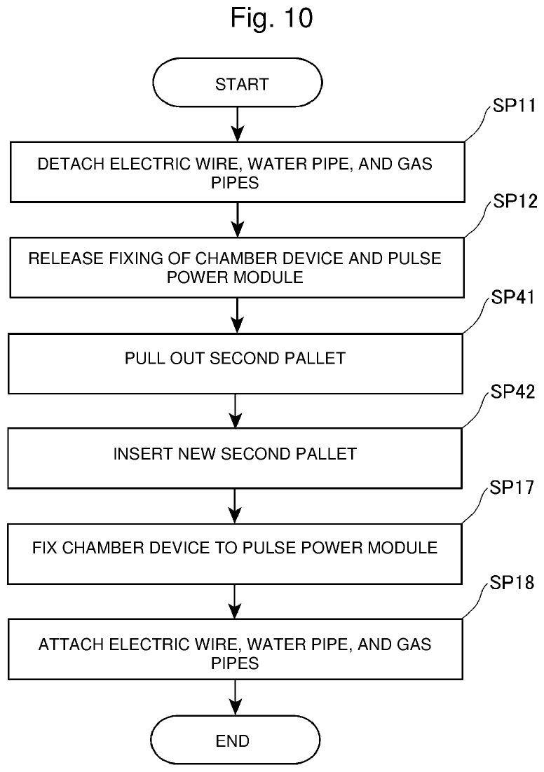

Next, another example of the maintenance method of the gas laser apparatus 100 in the present embodiment will be described. FIG. 10 is a diagram illustrating another example of the flowchart of the maintenance method of the gas laser apparatus 100 in the present embodiment. The maintenance method is performed at the time of periodic maintenance of the chamber device CH due to the deterioration of the electrodes 32a and 32b or the like as in the comparative example. The flowchart of the present embodiment differs from the flowcharts described in FIG. 4 and FIG. 5 in that it includes step SP41 and step SP42 instead of step SP13 to step SP16, and step SP19 to step SP21 are not required. In step SP12, when the fixing of the chamber device CH and the pulse power module 143 is released, the flow proceeds to step SP41. In the present flowchart, the charger 141 and the pulse power module 143 remain electrically connected to each other.

(Step SP41)

In the present step, the claw of the lift is inserted into the gap between the back surface of the second pallet 303 and the mounting surface 301a of the first pallet 301, and the second pallet 303 is lifted by the claw of the lift and is pulled out from the housing unit 120 by the lift. As a result, the chamber device CH is pulled out together with the second pallet 303. The pulled-out second pallet 303 is replaced with a new second pallet 303. Note that the charger 141, the pulse power module 143, and the first pallet 301 remain housed in the housing unit 120.

A new chamber device CH is positioned on the new second pallet 303 by the positioning unit 700. Note that the second pallet 303 may not be replaced, and the chamber device CH may be replaced with the new chamber device CH. Upon completion of the replacement, the flow proceeds to step SP42.

(Step SP42)

In the present step, the new second pallet 303 is supported on the bottom surface of the new second pallet 303 by the claw of the lift, and is inserted into the housing unit 120 by the lift. In the inserted new second pallet 303, the legs 511, 513 and 515 are individually mounted on the pedestals 521, 523 and 525, and the new second pallet 303 is positioned on the first pallet 301 by the positioning unit 500. Once the positioning is completed, the claw of the lift is pulled out from the housing unit 120 and the flow proceeds to step SP17.

In step SP17, once the chamber device CH is fixed to the pulse power module 143, the flow proceeds to step SP18 and ends.

As described above, in the present flowchart, the chamber device CH is replaced independently of the charger 141 and the pulse power module 143.

3.3 Operation and Effect

The gas laser apparatus 100 of the present embodiment includes the pulse power module 143 that is the voltage application circuit, the chamber device CH that includes the electrodes 32a and 32b and outputs the light generated when the voltage is applied to the electrodes 32a and 32b from the pulse power module 143, the first pallet 301 including the mounting surface 301a on which the chamber device CH and the pulse power module 143 are disposed in parallel with each other, and the housing unit 120 in and out of which the first pallet 301 is movable by being moved in the in-plane direction of the mounting surface 301a.

In the configuration, the first pallet 301 is pulled out from the housing unit 120 and replaced with a new first pallet 301 on which a new chamber device CH and a new pulse power module 143 are disposed in parallel. Further, the new first pallet 301 is inserted into the housing unit 120 and installed in the housing unit 120. Therefore, the pulse power module 143 does not need to be raised or lowered with respect to the chamber device CH as in the replacement of the comparative example, and replacement time can be shortened. In the configuration, the pulse power module 143 and the chamber device CH are replaced altogether with the first pallet 301. Therefore, as compared with a case where each of the pulse power module 143 and the chamber device CH is individually moved in and out and replaced, work processes for the replacement can be reduced, and the replacement time can be shortened.

In the configuration, the chamber device CH and the pulse power module 143 are disposed in parallel. Therefore, by having the first pallet 301 pulled out from the housing unit 120, the chamber device CH can be replaced without raising and lowering the pulse power module 143 as in the comparative example, and the replacement time can be shortened.

Next, differently from the gas laser apparatus 100 described above, a new chamber device CH and a new pulse power module 143 which are not disposed on the first pallet 301 and are connected to each other in a horizontal direction, that is, in the in-and-out direction will be described. When the new chamber device CH and the new pulse power module 143 are pushed into the housing unit 120 for the replacement, relative positional deviation may occur in the new chamber device CH and the new pulse power module 143 after installation. However, in the configuration, the new chamber device CH and the new pulse power module 143 are already disposed on the new first pallet 301. Therefore, even when the new first pallet 301 is pushed in, the relative positional deviation can be suppressed in the new chamber device CH and the new pulse power module 143 after the installation in the housing unit 120. When the relative positional deviation is suppressed, a change in a value of the voltage actually applied to the electrodes 32a and 32b with respect to a voltage value assumed in advance can be suppressed. Therefore, the gas laser apparatus 100 can output the light satisfying performance demanded from the exposure apparatus 200, and a decrease in reliability of the gas laser apparatus 100 can be suppressed.

The gas laser apparatus 100 of the present embodiment further includes the second pallet 303 on which the chamber device CH is disposed and which is disposed on the mounting surface 301a of the first pallet 301 and is movable in and out of the housing unit 120 by the movement in the in-plane direction of the mounting surface 301a independently of the first pallet 301. The chamber device CH is disposed on the mounting surface 301a of the first pallet 301 via the second pallet 303.

In the configuration, the chamber device CH can be replaced independently of the pulse power module 143 by moving the second pallet 303 in and out. In addition, in the replacement of the chamber device CH according to the configuration, as compared with the replacement of the chamber device CH of the comparative example, the need of raising and lowering the pulse power module 143 with respect to the chamber device CH can be eliminated, and the replacement time can be shortened.

The gas laser apparatus 100 of the present embodiment further includes the positioning unit 400 which is a first positioning unit for positioning the first pallet 301 in the housing unit 120. The positioning unit 400 includes the legs 411, 413 and 415 disposed on the bottom surface of the first pallet 301 and pedestals 421, 423 and 425 disposed in the housing unit 120. The leg 411, which is the first leg, is mounted on the pedestal 421, which is the first pedestal. The leg 413, which is the second leg, is mounted on the pedestal 423, which is the second pedestal, and is easy to move in the predetermined direction compared to the leg 411. The leg 415, which is the third leg, is mounted on the pedestal 425, which is the third pedestal, is easy to move in the in-plane direction of the mounting surface 301a compared to the leg 411, and is easy to move in the directions other than the predetermined direction compared to the leg 413.

In the gas laser apparatus 100 of the present embodiment, by the positioning unit 400, the time required for adjusting the position of the new first pallet 301 with respect to the housing unit 120 when installing the new first pallet 301 in the housing unit 120 can be shortened. Therefore, downtime of the gas laser apparatus 100 can be shortened.

Further, in the configuration, the gap is provided between the back surface of the first pallet 301 and the housing unit 120 by the legs 411, 413 and 415 and the pedestals 421, 423 and 425. Therefore, the claw of the lift can be inserted into and removed from the gap. In addition, at the time of the replacement, the first pallet 301 can be lifted by the claw inserted into the gap and pulled out from the housing unit 120, and the first pallet 301 can be inserted into the housing unit 120 in a state of being supported by the claw.

In the gas laser apparatus 100 of the present embodiment, at least a part of the pedestal 423 overlaps the pedestal 421 when viewed from the predetermined direction. When the pedestal 421 is viewed from above, at least a part of the pedestal 421 overlaps the optical axis C of the light traveling inside the chamber device CH.

In the chamber device CH of the present embodiment, the temperature inside the chamber device CH may increase when the voltage is applied to the electrodes 32a and 32b. As the temperature increases, the heat of the chamber device CH is transferred to the first pallet 301, and the first pallet 301 may be deformed due to the thermal expansion. In the configuration, since the first pallet 301 is deformed along the optical axis C even when it is deformed by the heat from the chamber device CH, the deviation of the optical axis C can be suppressed.

The gas laser apparatus 100 of the present embodiment further includes the positioning unit 500 which is a second positioning unit for positioning the second pallet 303 on the first pallet 301. The positioning unit 500 includes the legs 511, 513 and 515 disposed on the bottom surface of the second pallet 303, and pedestals 521, 523 and 525 disposed on the mounting surface 301a of the first pallet 301. The leg 511, which is the fourth leg, is mounted on the pedestal 521, which is the fourth pedestal. The leg 513, which is the fifth leg, is mounted on the pedestal 523, which is the fifth pedestal, and is easy to move in the specific direction compared to the leg 511. The leg 515, which is the sixth leg, is mounted on the pedestal 525, which is the sixth pedestal, is easy to move in the in-plane direction of the mounting surface 301a compared to the leg 511, and is easy to move in the directions other than the specific direction compared to the leg 513.

In the gas laser apparatus 100 of the present embodiment, by the positioning unit 500, the time required for adjusting the position of the new second pallet 303 with respect to the first pallet 301 when installing the new second pallet 303 on the first pallet 301 can be shortened. Therefore, the downtime of the gas laser apparatus 100 can be shortened.

Further, in the configuration, the gap is provided between the back surface of the second pallet 303 and the mounting surface 301a of the first pallet 301 by the legs 511, 513 and 515 and the pedestals 521, 523 and 525. Therefore, the claw of the lift can be inserted into and removed from the gap. In addition, at the time of the replacement, the second pallet 303 can be lifted and pulled out from the housing unit 120 by the claw inserted into the gap, and the second pallet 303 can be inserted into the housing unit 120 in a state of being supported by the claw.

In the gas laser apparatus 100 of the present embodiment, at least a part of the pedestal 423 overlaps the pedestal 421 when viewed from the predetermined direction. When the pedestal 421 is viewed from above, at least a part of the pedestal 421 overlaps the optical axis C of the light traveling inside the chamber device CH. At least a part of the pedestal 523 overlaps the pedestal 521 when viewed from the specific direction, and at least a part of the pedestal 521 overlaps the optical axis C of the light traveling inside the chamber device CH when the pedestal 521 is viewed from above. When the pedestal 521 is viewed from above, at least a part of the pedestal 521 overlaps the pedestal 421.

In the configuration, since the first pallet 301 and the second pallet 303 are deformed along the optical axis C even when they are deformed by the heat from the chamber device CH, the deviation of the optical axis C can be suppressed.

The gas laser apparatus 100 of the present embodiment further includes the heat insulating member 315 disposed between the chamber device CH and the first pallet 301.

In the configuration, deformation of the first pallet 301 due to the heat of the chamber device CH can be suppressed by the heat insulating member 315. When the deformation of the first pallet 301 is suppressed, the deviation of the traveling direction of the light output from the chamber device CH can be suppressed.

In the gas laser apparatus 100 of the present embodiment, the gap through which the cooling medium flows is provided between the bottom surface of the chamber device CH and the first pallet 301 by the legs 511, 513 and 515.

In the configuration, when the cooling medium flows through the gap, the deformation of the first pallet 301 due to the heat of the chamber device CH can be suppressed by the cooling medium. When the deformation of the first pallet 301 is suppressed, the deviation of the traveling direction of the light output from the chamber device CH can be suppressed.

The gas laser apparatus 100 of the present embodiment further includes the charger 141 disposed in parallel with the chamber device CH on the first pallet 301 when the chamber device CH is viewed from the front.

In the configuration, the charger 141 may also be replaced together with the chamber device CH and the pulse power module 143.

The gas laser apparatus 100 of the present embodiment further includes the positioning unit 700 that positions the chamber device CH on the second pallet 303.

In the configuration, the need of adjusting the position of the new chamber device CH after the installation in the housing unit 120 can be eliminated, and the downtime of the gas laser apparatus 100 can be shortened. In addition, in the configuration, the new first pallet 301 only needs to be pushed into the housing unit 120, and the need of pushing the new chamber device CH into the housing unit 120 can be eliminated. Further, the positional deviation of the new chamber device CH due to the pushing can be suppressed.

In the maintenance method of the gas laser apparatus 100 of the present embodiment, when the chamber device CH and the pulse power module 143 are to be replaced, the first pallet 301 is replaced altogether.

In the configuration, as compared with the case where each of the chamber device CH and the pulse power module 143 is individually moved in and out of the housing unit 120 and replaced, the work processes for the replacement can be reduced, and the replacement time can be shortened.

In the maintenance method of the gas laser apparatus 100 of the present embodiment, when the chamber device CH and the pulse power module 143 are to be replaced, the claw of the lift is inserted into the gap between the first pallet 301 and the housing unit 120, and the first pallet 301 is pulled out from the housing unit 120 by the claw.

In the replacement of the chamber device CH and the pulse power module 143 according to the configuration, as compared with the replacement of the chamber device CH and the pulse power module 143 of the comparative example, the need of raising and lowering the pulse power module 143 with respect to the chamber device CH can be eliminated. Therefore, the replacement time can be shortened.

In addition, in the maintenance method of the gas laser apparatus 100 of the present embodiment, when the chamber device CH is to be replaced, the second pallet 303 is replaced altogether.

In the configuration, the chamber device CH can be replaced independently of the pulse power module 143 by moving the second pallet 303 in and out. In addition, in the replacement of the chamber device CH according to the configuration, as compared with the replacement of the chamber device CH of the comparative example, the need of raising and lowering the pulse power module 143 with respect to the chamber device CH can be eliminated, and the replacement time can be shortened.

Further, in the maintenance method of the gas laser apparatus 100 of the present embodiment, when the chamber device CH is to be replaced, the claw of the lift is inserted into the gap between the first pallet 301 and the second pallet 303, and the second pallet 303 is pulled out from the housing unit 120 by the claw.

In the replacement of the chamber device CH according to the configuration, as compared with the replacement of the chamber device CH of the comparative example, the need of raising and lowering the pulse power module 143 with respect to the chamber device CH can be eliminated, and the replacement time can be shortened.

While the embodiment has been described as an example, the present disclosure is not limited thereto, and can be modified as appropriate.

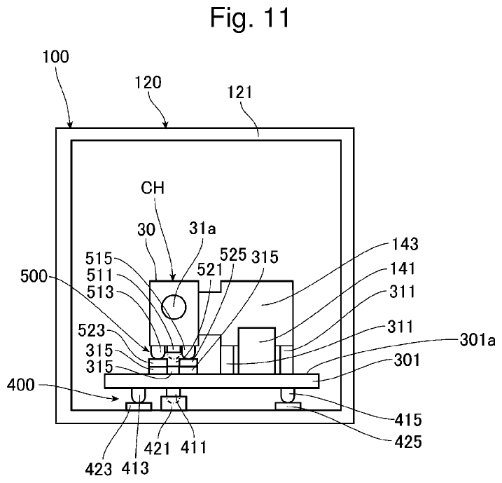

The chamber device CH is disposed on the mounting surface 301a of the first pallet 301 via the second pallet 303, but may be disposed directly on the mounting surface 301a of the first pallet 301. FIG. 11 is a side view of the housing unit 120 in a modification of the present embodiment. In the gas laser apparatus 100 of the present modification, the positioning unit 500 positions the chamber device CH on the first pallet 301. The legs 511, 513 and 515 of the positioning unit 500 of the present modification have the same configuration as the legs 711, 713 and 715 of the positioning unit 700 of the embodiment. The heat insulating members 315 of the present modification are disposed between the bottom surface of the housing 30 of the chamber device CH and the mounting surface 301a of the first pallet 301. The three heat insulating members 315 are disposed on the mounting surface 301a, and pedestals 521, 523 and 525 are individually disposed on each of the heat insulating members 315. In the configuration, the need of the second pallet 303 can be eliminated, weight applied to the first pallet 301 can be smaller as compared with the case where the second pallet 303 is used, and the need of the work of disposing the second pallet 303 on the first pallet 301 can be eliminated.

In the positioning unit 400 of the embodiment, the configuration of the legs and the configuration of the pedestals may be reversed. In this case, the upper surface of the pedestals 421, 423 and 425 may be provided with a hemispherical projection, the head of the leg 411 may be provided with a depression, the head of the leg 413 may be provided with a groove having a V-shaped cross section, and the head of the leg 415 may be a flat surface. In the positioning units 500 and 700 as well, the configuration of the legs and the configuration of the pedestals may be reversed. Further, in the positioning unit 400, the legs and the pedestals may be reversely disposed, the pedestals 421, 423 and 425 may be disposed on the bottom surface of the first pallet 301, and the legs 411, 413 and 415 may be disposed in the housing unit 120. In the positioning units 500 and 700 as well, the legs and the pedestals may be reversely disposed. In addition, the shape of the head of the leg is not particularly limited.

Further, in the embodiment, the pedestals 721, 723 and 725 may not be disposed, and the chamber device CH may be disposed on the second pallet 303 via the legs 711, 713 and 715. Further, in the modification, the pedestals 521, 523 and 525 may not be disposed, and the chamber device CH may be disposed on the first pallet 301 via the legs 511, 513 and 515.

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious for those skilled in the art that the embodiment of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A gas laser apparatus comprising:
a voltage application circuit;
a chamber device that includes an electrode and is configured to output light generated when a voltage is applied to the electrode from the voltage application circuit;
a first pallet that includes a mounting surface on which the chamber device and the voltage application circuit are disposed in parallel with each other; and
a housing unit in and out of which the first pallet is movable by movement in an in-plane direction of the mounting surface.

2. The gas laser apparatus according to claim 1, further comprising
a second pallet on which the chamber device is disposed and which is disposed on the mounting surface of the first pallet and is movable in and out of the housing unit by movement in the in-plane direction independently of the first pallet, wherein
the chamber device is disposed on the mounting surface of the first pallet via the second pallet.

3. The gas laser apparatus according to claim 1, further comprising
a first positioning unit configured to position the first pallet in the housing unit, wherein
the first pallet includes
a first leg, a second leg, and a third leg that are disposed on a bottom surface of the first pallet and extend toward the housing unit, and
a first pedestal, a second pedestal, and a third pedestal that are disposed in the housing unit,
the first leg is mounted on the first pedestal,
the second leg is mounted on the second pedestal and is easy to move in a predetermined direction of the in-plane direction compared to the first leg, and
the third leg is mounted on the third pedestal, is easy to move in the in-plane direction compared to the first leg, and is easy to move in directions other than the predetermined direction compared to the second leg.

4. The gas laser apparatus according to claim 3, wherein
at least a part of the second pedestal overlaps the first pedestal when viewed from the predetermined direction.

5. The gas laser apparatus according to claim 4, wherein
at least a part of the first pedestal overlaps an optical axis of the light traveling inside the chamber device when the first pedestal is viewed from above.

6. The gas laser apparatus according to claim 3, further comprising
a second pallet on which the chamber device is disposed and which is disposed on the mounting surface of the first pallet and is movable in and out of the housing unit by movement in the in-plane direction independently of the first pallet, and
a second positioning unit configured to position the second pallet on the first pallet, wherein
the chamber device is disposed on the mounting surface of the first pallet via the second pallet,
the second positioning unit includes
a fourth leg, a fifth leg, and a sixth leg that are disposed on a bottom surface of the second pallet and extend toward the first pallet, and
a fourth pedestal, a fifth pedestal, and a sixth pedestal that are disposed on the mounting surface of the first pallet,
the fourth leg is mounted on the fourth pedestal,
the fifth leg is mounted on the fifth pedestal and is easy to move in a specific direction in the in-plane direction compared to the fourth leg, and
the sixth leg is mounted on the sixth pedestal, is easy to move in the in-plane direction compared to the fourth leg and is easy to move in directions other than the specific direction compared to the fifth leg.

7. The gas laser apparatus according to claim 6, wherein
at least a part of the second pedestal overlaps the first pedestal when viewed from the predetermined direction, and
at least a part of the fifth pedestal overlaps the fourth pedestal when viewed from the specific direction.

8. The gas laser apparatus according to claim 7, wherein
at least a part of the first pedestal overlaps an optical axis of the light traveling inside the chamber device when the first pedestal is viewed from above, and
at least a part of the fourth pedestal overlaps the optical axis of the light traveling inside the chamber device when the fourth pedestal is viewed from above.

9. The gas laser apparatus according to claim 8, wherein
at least a part of the fourth pedestal overlaps the first pedestal when the fourth pedestal is viewed from above.

10. The gas laser apparatus according to claim 1, further comprising
a heat insulating member disposed between the chamber device and the first pallet.

11. The gas laser apparatus according to claim 1, wherein
the chamber device includes a plurality of legs that are disposed on a bottom surface of the chamber device, extend toward the first pallet and are provided apart from each other in the in-plane direction, and
a gap in which a cooling medium flows is provided between the bottom surface of the chamber device and the first pallet by the legs.

12. The gas laser apparatus according to claim 1, further comprising
a charger disposed in parallel with the chamber device on the first pallet when the chamber device is viewed from front.

13. A gas laser apparatus maintenance method, comprising,
when replacing a chamber device and a voltage application circuit of a gas laser apparatus including
the voltage application circuit,
the chamber device that includes an electrode and is configured to output light generated when a voltage is applied to the electrode from the voltage application circuit,
a first pallet that includes a mounting surface on which the chamber device and the voltage application circuit are disposed in parallel with each other, and
a housing unit in and out of which the first pallet is movable by movement in an in-plane direction of the mounting surface,
replacing the first pallet altogether.

14. The gas laser apparatus maintenance method according to claim 13, wherein
the first pallet includes a plurality of legs that are disposed on a bottom surface of the first pallet, extend toward the housing unit and are provided apart from each other in the in-plane direction,
a gap is provided between the bottom surface of the first pallet and the housing unit by the legs, and
when the chamber device and the voltage application circuit are to be replaced, a claw of a lift is inserted into the gap, and the first pallet is pulled out from the housing unit by the claw.

15. The gas laser apparatus maintenance method according to claim 13, wherein
the first pallet is replaced altogether when an abnormality occurs in the gas laser apparatus.

16. The gas laser apparatus maintenance method according to claim 13, wherein
the gas laser apparatus further comprises a second pallet on which the chamber device is disposed and which is disposed on the first pallet and is movable in and out of the housing unit by movement in the in-plane direction independently of the first pallet,
the chamber device is disposed on the mounting surface of the first pallet via the second pallet, and
when the chamber device is to be replaced, the second pallet is replaced altogether.

17. The gas laser apparatus maintenance method according to claim 16, wherein
the second pallet includes a plurality of legs that are disposed on a bottom surface of the second pallet, extend toward the first pallet and are provided apart from each other in the in-plane direction,
a gap is provided between the bottom surface of the second pallet and the first pallet by the legs, and
when the chamber device is to be replaced, a claw of a lift is inserted into the gap, and the second pallet is pulled out from the housing unit by the claw.

18. The gas laser apparatus maintenance method according to claim 16, further comprising
replacing the second pallet altogether at a time of periodic maintenance of the chamber device.

19. An electronic device manufacturing method, comprising:
generating a laser beam by a gas laser apparatus, the gas laser apparatus including
a voltage application circuit,
a chamber device that includes an electrode and is configured to output light generated when a voltage is applied to the electrode from the voltage application circuit,
a first pallet that includes a mounting surface on which the chamber device and the voltage application circuit are disposed in parallel with each other, and
a housing unit in and out of which the first pallet is movable by movement in an in-plane direction of the mounting surface;
outputting the laser beam to an exposure apparatus; and
exposing a photosensitive substrate to the laser beam within the exposure apparatus to manufacture an electronic device.
